(19) United States
(12) Patent Application Publication
(10) Pub. No.: US 2017/0179080 A1
(43) Pub. Date: Jun. 22, 2017

(54) SEMICONDUCTOR PACKAGE INTERPOSER HAVING ENCAPSULATED INTERCONNECTS

(71) Applicant: Intel Corporation, Santa Clara, CA (US)

(72) Inventors: Akshay MATHKAR, Tempe, AZ (US); Nachiket Raghunath RARAVIKAR, Gilbert, AZ (US); Donald Tiendung TRAN, Phoenix, AZ (US); Jerry Lee JENSEN, Maricopa, AZ (US); Javier A. FALCON, Chandler, CA (US); William Nicholas LABANOK, Gilbert, AZ (US); Robert Leon SANKMAN, Phoenix, AZ (US); Robert Allen STINGEL, Gilbert, AZ (US)

(21) Appl. No.: 14/975,128

(22) Filed: Dec. 18, 2015

(51) Int. Cl. H01L 25/065; H01L 23/29; H05K 1/02; H01L 21/56; H01L 25/00; H05K 1/11; H01L 23/498; H01L 21/48

(52) U.S. Cl. CPC H01L 25/0657; H01L 23/49827; H01L 23/49838; H01L 23/293; H01L 23/49811; H01L 21/4853; H01L 21/486; H01L 21/56; H01L 25/50; H05K 1/115; H05K 1/0298; H01L 2225/06548; H01L 2225/06555

(57) ABSTRACT

Semiconductor package interposers having high-density and high-aspect ratio encapsulated interconnects, and semiconductor package assemblies incorporating such interposers, are described. In an example, a semiconductor package interposer includes several conductive interconnects encapsulated in a polymer substrate and having height dimensions greater than a cross-sectional dimension. The semiconductor package interposer may support a first semiconductor package above a second semiconductor package and may electrically connect die pins of the first semiconductor package to die pins of the second semiconductor package.

### TECHNICAL FIELD

Embodiments of the invention are in the field of semiconductor packages and, in particular, semiconductor package interposers having encapsulated conductive interconnects.

### BACKGROUND

Semiconductor packages are used for protecting an integrated circuit (IC) chip or die, and also to provide the die with an electrical interface to external circuitry, e.g., a printed circuit board (PCB). With the increasing demand for smaller electronic devices, semiconductor packages are designed to be even more compact and must support larger circuit density. To save lateral space on the PCB, packaging methods such as “package on package” methods are used to vertically stack one semiconductor package, e.g., a memory package, on another semiconductor package, e.g., a central processing unit (CPU) package. Historically, low density interconnects, e.g., solder balls, have been used to connect the memory package to the CPU package.

### BRIEF DESCRIPTION OF THE DRAWINGS

FIG. 1 illustrates a sectional view of a semiconductor package assembly having one semiconductor package supported above another semiconductor package by an interposer, in accordance with an embodiment.

FIG. 2 illustrates a perspective view of an interposer having encapsulated conductive interconnects, in accordance with an embodiment.

FIG. 3 illustrates a sectional view, taken about line A-A of FIG. 2, of an interposer having encapsulated conductive interconnects, in accordance with an embodiment.

FIG. 4 illustrates a sectional view, taken about line B-B of FIG. 2, of an interposer having encapsulated conductive interconnects, in accordance with an embodiment.

FIG. 5 illustrates a flowchart of a method of manufacturing an interposer and a semiconductor package assembly having the interposer, in accordance with an embodiment.

FIGS. 6A-6D illustrate an interposer after various operations of a method of manufacturing the interposer, in accordance with an embodiment.

FIG. 7 is a schematic of a computer system, in accordance with an embodiment.

### DESCRIPTION OF EMBODIMENTS

Semiconductor package interposers having encapsulated conductive interconnects, and semiconductor package assemblies having such interposers, are described. In the following description, numerous specific details are set forth, such as packaging and interconnect architectures, in order to provide a thorough understanding of embodiments of the present invention. It will be apparent to one skilled in the art that embodiments of the present invention may be practiced without these specific details. In other instances, well-known features, such as specific semiconductor fabrication processes, are not described in detail in order to not unnecessarily obscure embodiments of the present invention. Furthermore, it is to be understood that the various embodiments shown in the Figures are illustrative representations and are not necessarily drawn to scale.

Existing package on package (PoP) designs, including so-called “through mold interconnect” architectures, utilize interconnects to physically and electrically connect a memory package to an underlying logic package. Such interconnects include solder balls or electroplated copper bumps, which due to practical limitations, are ordinarily formed to have aspect ratios (height divided by cross-sectional dimension) of less than 1.5, e.g., 1.0 or less. Thus, to achieve a necessary vertical offset between the memory package and the logic package, existing interconnects are formed with a cross-sectional dimension that limits a minimum interconnect pitch and/or a minimum inter-interconnect distance. Consequently, existing PoP designs have limited interconnect densities. Accordingly, as memory requirements of electronic devices increase, such PoP designs may be unable to achieve a required reduction in interconnect pitch.

In an aspect, a semiconductor package interposer and/or a semiconductor package assembly incorporating such an interposer, includes several conductive interconnects encapsulated by a polymer substrate. The encapsulated interconnects may extend in a longitudinal direction, e.g., parallel to each other, through the polymer substrate, and thus, the polymer substrate may support and bind the interconnects together. As such, the interposer may have a thin, sheet-like profile, and may provide sufficient column strength to support a semiconductor package having a memory die over a semiconductor package having a logic die. Furthermore, the buttressed interconnects may be formed with aspect ratios greater than 1.0, e.g., greater than 1.5 or more, and may have a pitch that allows for a high density of interconnects compared to currently available technology options for PoP interconnects.

In an aspect, a method of manufacturing an interposer having several conductive interconnects encapsulated by a polymer substrate allows for high volume manufacturing of high-density, high-aspect ratio interconnects. The method may utilize scalable processes such as stamping and injection molding, e.g., overmolding, to produce the interposers in a low-cost process flow. That is, the manufacturing process flow may be less costly than processes used to fabricate currently available technology options for PoP interconnects. For example, the process flow may eliminate the need for costly and difficult laser-drilling processes used for through mold interconnect architectures.

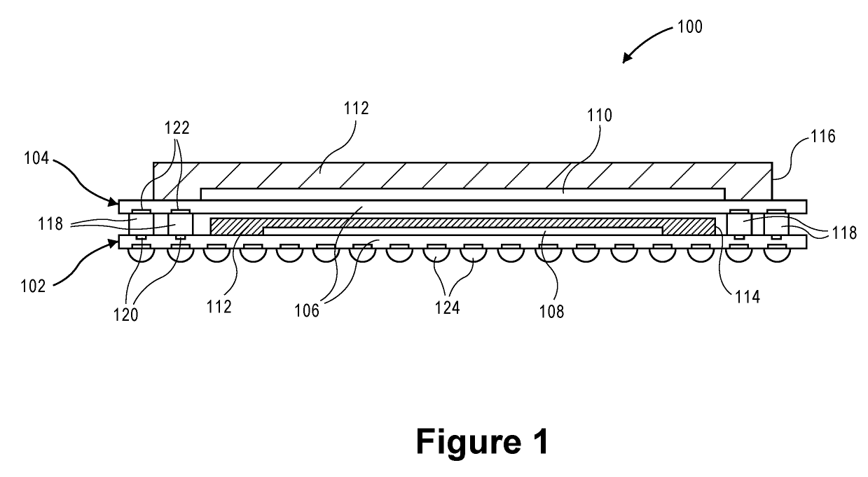

Referring to FIG. 1, a sectional view of a semiconductor package assembly having one semiconductor package supported above another semiconductor package by an interposer is illustrated in accordance with an embodiment. A semiconductor package assembly 100 may include a first semiconductor package 102 and a second semiconductor package 104 stacked on each other. For example, second semiconductor package 104 may be stacked over first semiconductor package 102, and thus, semiconductor package assembly 100 may have a PoP architecture.

Each semiconductor package may include a respective die mounted on a respective package substrate 106. For example, first semiconductor package 102 may include a logic die 108, e.g., a central processing unit die, mounted on a respective laminate package substrate 106, and second semiconductor package 104 may include a memory die 110 mounted on a respective laminate package substrate 106. The dies may be sandwiched between the respective package substrates 106 and a respective mold compound forming a top case 112 of the respective packages. The top cases may have respective geometric shapes, e.g., a box shape having sides. For example, first semiconductor package 102 may have a respective top case 112 that includes a first package side 114 facing a lateral direction, and second semiconductor package 104 may have a respective top case 112 that includes a second package side 116 facing the lateral direction. Thus, one or more of the package sides of first semiconductor package 102 or second semiconductor package 104 may be parallel planar faces.

One or more interposers 118 may support the second semiconductor package 104 over the first semiconductor package 102. More particularly, interposers 118 may support memory die 110 above logic die 108. In an embodiment, interposers 118 function as columns to vertically offset a bottom surface of package substrate 106 of second semiconductor package 104 from a top surface of top case 112 of first semiconductor package 102. Thus, interposers 118 create a physical gap between first semiconductor package 102 and second semiconductor package 104.

Interposers 118 may be attached to substrate(s) 106 of semiconductor packages(s) 102, 104 using a variety of processing techniques. For example, solder pastes or conducting sinterable adhesives may be applied, e.g., stencil printed, between interposers 118 and corresponding contact pads 120, 122. A reflow process may then be used to form metallurgical joints between the components. Optionally, interconnect joints between interposers 118 and corresponding contact pads 120, 122 may be underfilled to minimize contact stresses. In an embodiment, a process flow for attaching interposer 118 to substrates 106 may include attaching interposer 118 to substrate 106 of semiconductor package 102 and attaching interposer 118 to substrate 106 of semiconductor package 104, and such attachments may be made sequentially and in any order. Attachments between interposer 118 and corresponding substrates 106 may not only include solder bonds, but may also include conducting non-solder bonds. For example, conducting adhesive bonds and/or press fit attachments between portions of interposer 118 and substrates 106 may be used in addition to, or instead of, metallurgical joints formed between the components. Such variations will be understood by one skilled in the art in light of the description below.

In addition to maintaining an offset between the semiconductor packages of semiconductor package assembly 100, interposers 118 may electrically connect first semiconductor package 102 to second semiconductor package 104. First semiconductor package 102 may include first contact pads 120 on a top surface of the respective package substrate 106. Similarly, second semiconductor package 104 may include second contact pads 122 on a bottom surface of the respective package substrate 106. The contact pads 120, 122 of the semiconductor packages 102, 104 may carry electrical signals, e.g., power or I/O signals, between the dies of semiconductor package assembly 100. Similarly, the contact pads 120, 122 of the semiconductor package 102, 104 may carry electrical signals between the dies and external circuitry of a printed circuit board (not shown) connected to one or more solder balls 124 of semiconductor package assembly 100. Accordingly, the interposers 118 may include interconnects having ends that are electrically connected to respective contact pads to carry the electrical signals between first contact pads 120 of first semiconductor package 102 and second contact pads 122 of second semiconductor package 104.

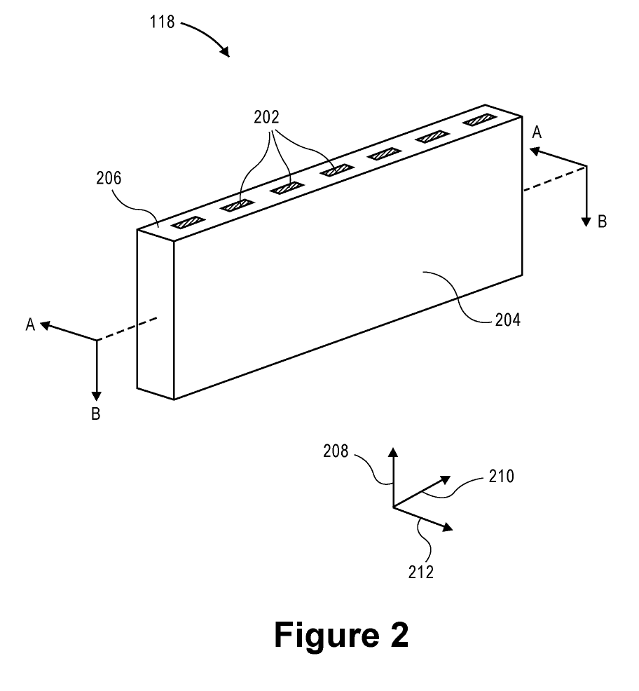

Referring to FIG. 2, a perspective view of an interposer having encapsulated conductive interconnects is illustrated in accordance with an embodiment. A semiconductor package interposer 118 may include several conductive interconnects 202 encapsulated by a polymer substrate 204. For example, the polymer substrate 204 may include a first end face 206 separated from a second end face (hidden) in a longitudinal direction 208, and the conductive interconnects 202 may extend in the longitudinal direction 208 through the polymer substrate 204. Longitudinal direction 208 may be the direction between the ends of the conductive interconnects 202 that are electrically connected to first contact pads 120 or second contact pads 122. More particularly, longitudinal direction 208 may be a direction of a column height of interposer 118 and/or conductive interconnects 202. Thus, longitudinal direction 208 may be distinguished from a transverse direction 210, i.e., a direction orthogonal to longitudinal direction 208 along a long side of polymer substrate 204, or a depth direction 212, i.e., a direction orthogonal to longitudinal direction 208 and transverse direction 210 along a short side of polymer substrate 204.

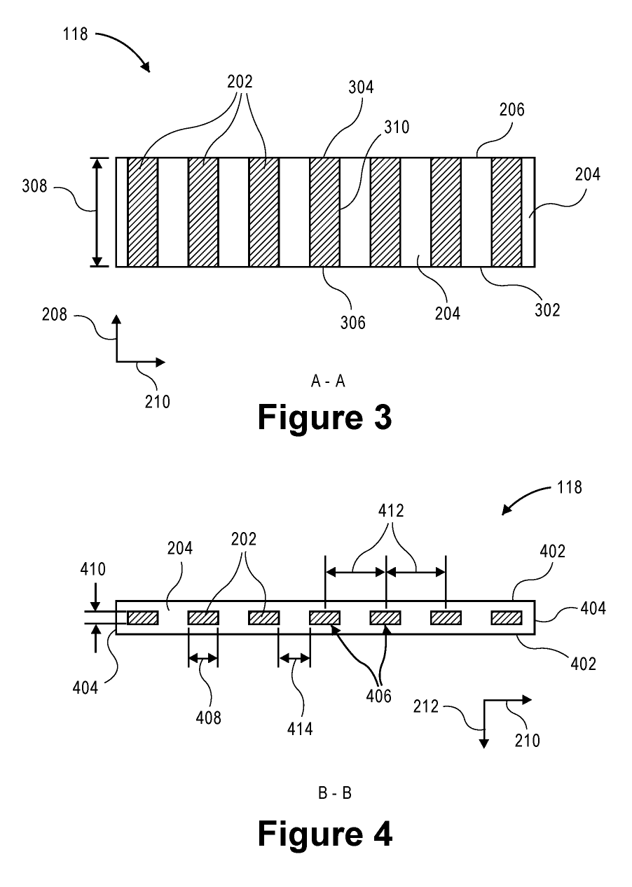

Referring to FIG. 3, a sectional view, taken about line A-A of FIG. 2, of an interposer having encapsulated conductive interconnects is illustrated in accordance with an embodiment. Conductive interconnects 202 may extend in longitudinal direction 208 from first end face 206 of polymer substrate 204 to a second end face 302 of polymer substrate 204 thus, each conductive interconnect 202 may include a respective first end 304 exposed at first end face 206 and a respective second end 306 exposed at second end face 302. A distance in longitudinal direction 208 between first end 304 and second end 306 of conductive interconnect 202 may be considered a height 308 of conductive interconnect 202. Respective sides 310 of each conductive interconnect 202 may extend between first end 304 and second end 306 of conductive interconnect 202, and polymer substrate 204 may surround sides 310 such that conductive interconnect 202 is encapsulated by polymer substrate 204. Thus, it is noted that conductive interconnect 202 may be encapsulated by polymer substrate 204 when the ends of conductive interconnect 202 are exposed and uncovered by polymer substrate 204.

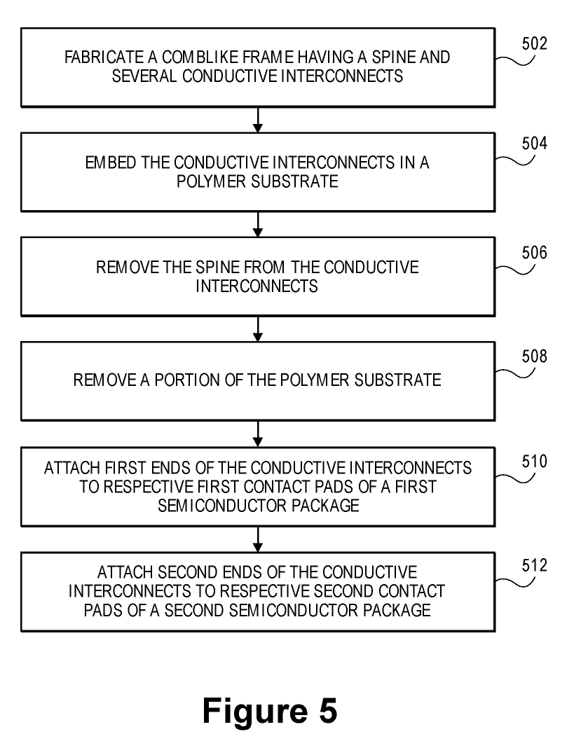

Referring to FIG. 4, a sectional view, taken about line B-B of FIG. 2, of an interposer having encapsulated conductive interconnects is illustrated in accordance with an embodiment. Polymer substrate 204 may include a polymer sheet encapsulating conductive interconnects 202. That is, polymer substrate 204 may be thin in comparison to its length and breadth. As such, polymer substrate 204 may have sidewall faces 402 separated from one another in depth direction 212 and extending from first end face 206 to second end face 302 in longitudinal direction 208 and between end walls 404 in transverse direction 210. Accordingly, conductive interconnects 202 may be surrounded by the end walls 404 and sidewall faces 402 of polymer substrate 204.

In an embodiment, conductive interconnects 202 may extend parallel to each other through polymer substrate 204. For example, conductive interconnects 202 may include rods of conductive material, such as copper or aluminum, having respective axes that run through polymer substrate 204 in a parallel direction, e.g., in longitudinal direction 208 or diagonally between first end face 206 and second end face 302 of polymer substrate 204. The axes of conductive interconnects 202 may be nonlinear. For example, conductive interconnects 202 may extend along a serpentine and/or curvilinear path between first end face 206 and second end face 302. Conductive interconnects 202 may conform to each other. For example, when conductive interconnects 202 extend along a zigzag path, conductive interconnects 202 may include bends that intermesh with one another. Accordingly, each conductive interconnect 202 may include height 308 between first end face 206 and second end face 302 of polymer substrate 204, and a path of conductive interconnect 202 over height 308 may include linear and/or nonlinear segments.

Conductive interconnect 202 may include a cross-section 406 orthogonal to the interconnect axis between first end face 206 and second end face 302 of polymer substrate 204. For example, in a case where conductive interconnects 202 extend vertically along a linear path from first end face 206 to second end face 302 (FIG. 3) cross-section 406 may be orthogonal to longitudinal direction 208. Cross-section 406 may be rectangular, or have any other cross-sectional shape or area. For example, cross-section 406 may be circular, triangular, polygonal, etc. Thus, conductive interconnect 202 may have a dimension across cross-section 406. For example, when cross-section 406 is rectangular, the dimension across cross-section 406 may be a width dimension 408 in transverse direction 210 or a depth dimension 410 in depth direction 212. Similarly, when cross-section 406 is circular, the dimension across cross-section 406 may be a diameter. In an embodiment, the dimension is in a range of 50 to 200 microns. For example, width dimension 408 may be in a range of 50 to 100 microns, e.g., 75 microns, and depth dimension 410 may be in a range of 100 to 200 microns, e.g., 150 microns.

An aspect ratio of conductive interconnects 202 may be greater than one. For example, one or more of the conductive interconnects 202 of interposer 118 may have height 308 that is greater than the dimension of cross-section 406. For example, height 308 may be at least 1.1 times, e.g., at least 1.5 times, greater than the dimension of cross-section 406. In an embodiment, height 308 is in a range of 1 to 5 times, e.g., 1.5 to 3 times, greater than the dimension of cross-section 406. By way of example, when conductive interconnect 202 includes width dimension 408 in a range of 50 to 100 microns, height 308 may be in a range of 75 to 300 microns. Accordingly, conductive interconnects 202 may be longer, e.g., taller, than they are wide to maintain a vertical offset between stacked semiconductor packages while also allowing for more interconnects per unit area within a plane orthogonal to longitudinal direction 208.

The dimension across cross-section 406 of conductive interconnects 202 may be sized according to the contact pads to which the interconnect attaches. For example, the dimension may be the same as, or slightly smaller than, a diameter of first contact pads 120 or second contact pads 122. Furthermore, a distance between conductive interconnects 202 of interposer 118 may correspond to a separation between contact pads 120, 122 to which the interconnects attach. In an embodiment, a pitch 412 of conductive interconnects 202 in transverse direction 210 may be a predetermined distance corresponding to a pitch of the contact pads. Pitch 412 of conductive interconnects 202 may be defined as a center-to-center distance between adjacent interconnects. For example, when conductive interconnects 202 are rectangular rods having respective interconnect axes running parallel to each other, pitch 412 of the interconnects may be a distance between the interconnect axes, perpendicular to the interconnect axes. In an embodiment, conductive interconnects 202 have pitch 412 in a range of 200 to 250 microns, e.g., 225 microns. It will be appreciated that an edge distance 414, i.e., a distance between edges of neighboring conductive interconnects, may also correspond to a separation distance between contact pads of the semiconductor packages. In an embodiment, edge distance 414 may be in a range of 100 to 200 microns, e.g., 150 microns. This distance between neighboring conductive interconnects 202 may be filled by polymer substrate 204.

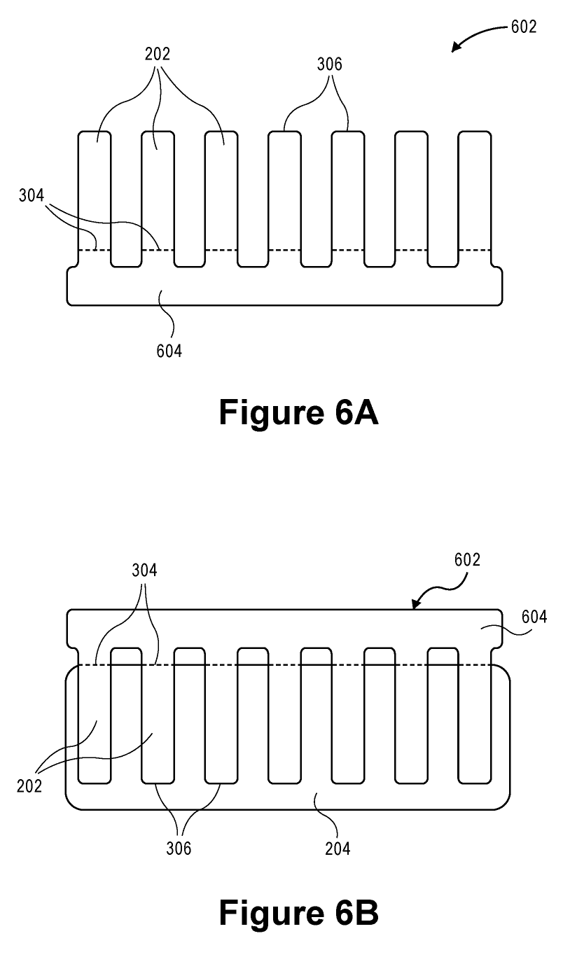

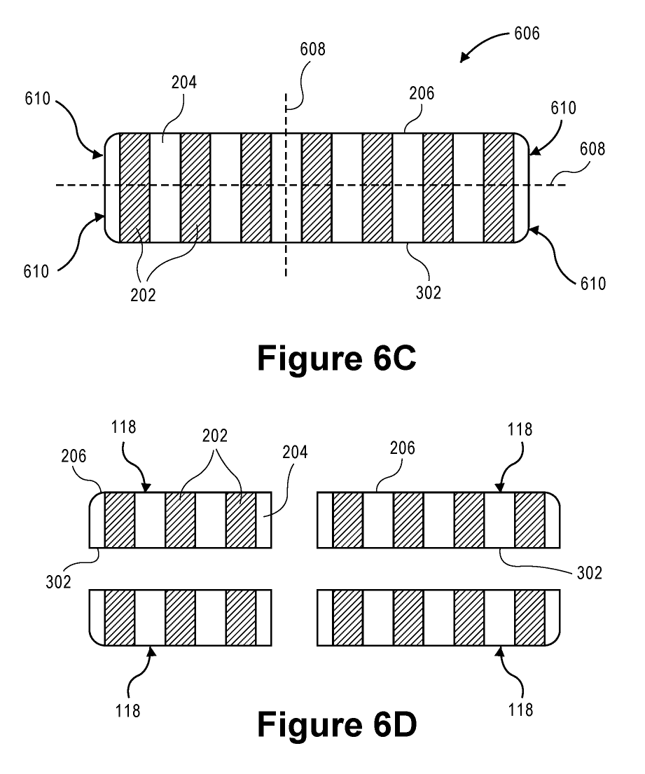

Referring to FIG. 5, a flowchart of a method of manufacturing an interposer and a semiconductor package assembly having the interposer is illustrated in accordance with an embodiment. FIGS. 6A-6D illustrate an interposer after various operations of the method illustrated in FIG. 5. Thus, the corresponding figures will be described together below.

At operation 502, a comblike frame 602 may be fabricated. Referring to FIG. 6A, a side view of a comblike frame 602 is shown. Comblike frame 602 may include a structure having a spine 604 attached to several conductive interconnects 202. For example, conductive interconnects 202 may extend in longitudinal direction 208 from respective first ends 304 at spine 604 (represented by dotted lines through the comblike frame 602) to respective second ends 306 along an interconnect axis orthogonal to spine 604.

In an embodiment, comblike frame 602 may be fabricated from a sheet of conductive material. For example, comblike frame 602 may be stamped, etched, ablated, or otherwise formed from a copper sheet. Comblike frame 602 may be formed from a tungsten-based material to fabricate conductive interconnects 202 having a higher stiffness, as compared to copper. Such processes are well-known, and allow for high volume manufacturing of comblike frame 602 having tight tolerances.

At operation 504, conductive interconnects 202 of comblike frame 602 may be embedded in polymer substrate 204. Referring to FIG. 6B, a sectional view of comblike frame 602 embedded in polymer substrate 204 is shown. Embedding conductive interconnects 202 in polymer substrate 204 may include encapsulating one or more of spine 604 or second ends 306 of conductive interconnects 202 in polymer substrate 204. For example, conductive interconnects 202 may extend through polymer substrate 204 from first ends 304 to second ends 306. Polymer substrate 204 may be injection molded around conductive interconnects 202 and/or spine 604. For example, polymer substrate 204 may be overmolded around conductive interconnects 202 and second ends 306 of conductive interconnects 202 (as shown). Polymer substrate 204 may also be overmolded around spine 604 (not shown). Accordingly, conductive interconnects 202 and/or spine 604 may be potted within polymer substrate 204.

The choice of polymer used for molding or potting comblike frame 602 may vary depending upon the interconnect application requirements. For example, the polymer material may be a mold compound having an epoxy filled with ceramic particles, neat or filled liquid crystal polymers, or a soft polymer such as polydimethylsiloxane, to name only a few possible material choices.

Referring to FIG. 6C, a sectional view of conductive interconnects 202 embedded in polymer substrate 204 is shown. At operation 506, spine 604 may be removed from conductive interconnects 202 to expose first ends 304 of conductive interconnects 202 at first end face 206 of polymer substrate 204. Furthermore, at operation 508, a portion of polymer substrate 204 may be removed to expose second ends 306 of conductive interconnects 202 at a second end face 302 of polymer substrate 204. By comparing FIG. 6C to FIG. 6B, it is apparent that the portion of embedded comblike frame 602 removed at operation 506 may be that portion having spine 604 and regions of conductive interconnects 202 above first ends 304. Removal of the spine 604 may include cutting polymer substrate 204 and conductive interconnects 202 in transverse direction 210 orthogonal to longitudinal direction 208 of conductive interconnects 202. Similarly, it is apparent that the portion of polymer substrate 204 removed at operation 508 may be that portion of embedded comblike frame 602 below second ends 306. Removal of the portion of polymer substrate 204 may include cutting polymer substrate 204 and conductive interconnects 202 in transverse direction 210. Cutting may be performed by slicing and/or back-grinding. Thus, an interposer blank 606 may be formed having several conductive interconnects 202 encapsulated by polymer substrate 204. Interposer blank 606 may be used as an interposer 118 in semiconductor package assembly 100, or may be segmented along arbitrary section lines 608 into various interposer sections 610, of which four are shown in FIG. 6C.

Referring to FIG. 6D, interposer blank 606 may be sectioned along section lines 608 to separate interposer sections 610 into individual interposers 118. For example, interposer blank 606 may be sliced using cutting techniques such as diamond saw or water jet cutting. Accordingly, interposer blank 606 may be segmented to achieve interposers 118 having predetermined dimensions and respective end faces 206, 302. For example, interposer blank 606 may have a height 308 in longitudinal direction 208 of 15 millimeters, and after sectioning interposer blank 606, each of the resultant interposers 118 may have individual heights 308 of 300 microns. Thus, many interposers 118 may be derived from a single interposer blank 606. Such scalability also allows for many conductive interconnects 202 to be included in each interposer 118. For example, each interposer 118 may have hundreds of conductive interconnects 202 arranged sequentially in transverse direction 210. Similarly, a number of interconnects 202 in each segmented interposer 118 may vary (as shown, some segmented interposers 118 have three interconnects and some have four, by way of example). Accordingly, the method of fabricating interposers 118 may be low-cost, repeatable, and scalable.

After segmenting interposer blank 606 into individual interposers 118, one or more interposers 118 may be used to physically and electrically connect first semiconductor package 102 to second semiconductor package 104 in semiconductor package assembly 100. For example, at operation 510, first ends 304 of conductive interconnects 202 may be attached to respective first contact pads 120 of first semiconductor package 102. Similarly, at operation 512, second ends 306 of conductive interconnects 202 may be attached to respective second contact pads 122 of second semiconductor package 104. Thus, first ends 304 may be electrically connected to respective first contact pads 120 of first semiconductor package 102, and second ends 306 may be electrically connected to respective second contact pads 122 of second conductor package.

Attaching the ends of conductive interconnects 202 of interposer 118 to respective contact pads on semiconductor packages 102, 104 may be achieved through a solder reflow process. For example, a solder paste may be printed on contact pads 120, 122 on first semiconductor package 102 and/or contact pads 122 on second semiconductor package 104, and interposers 118 may be picked and placed onto the packages to metallurgically bond the conductive interconnects 202 to the solder paste in a solder reflow process. In an embodiment, conductive interconnects 202 of interposers 118 may be joined directly to pins of the semiconductor package dies. For example, interposer 118 may be picked and placed directly on logic die 108 to bond conductive interconnects 202 to power and/or I/O pins of logic die 108.

In an embodiment, interposers 118 may be attached to first and second semiconductor packages 102, 104 such that respective sidewall faces 402 of interposers 118 face a same direction as package sides of the semiconductor packages. For example, polymer substrate 204 of interposer 118 may have sidewall face 402 extending parallel to first package side 114 and second package side 116 illustrated in FIG. 1. Accordingly, interposer 118 may be oriented lengthwise in a direction of the package sides to support each of the lateral edges of second semiconductor package 104 above corresponding edges of first semiconductor package 102.

Also illustrated in FIG. 1, semiconductor package assembly 100 may include multiple rows of interposers 118 adjacent to each other. For example, two interposers 118 are shown between first semiconductor package 102 and second semiconductor package 104 in both the left-hand and the right-hand regions of semiconductor package assembly 100. Given the high aspect ratio of conductive interconnects 202 within interposers 118, and the ability to closely pack several rows of interposers 118 in semiconductor package assembly 100, thousands of conductive interconnects 202 may be provided between stacked semiconductor packages 102, 104 of semiconductor package assembly 100. Accordingly, semiconductor package assembly 100 may have high-density conductive interconnects 202 to accommodate future increases in electronic device memory requirements.

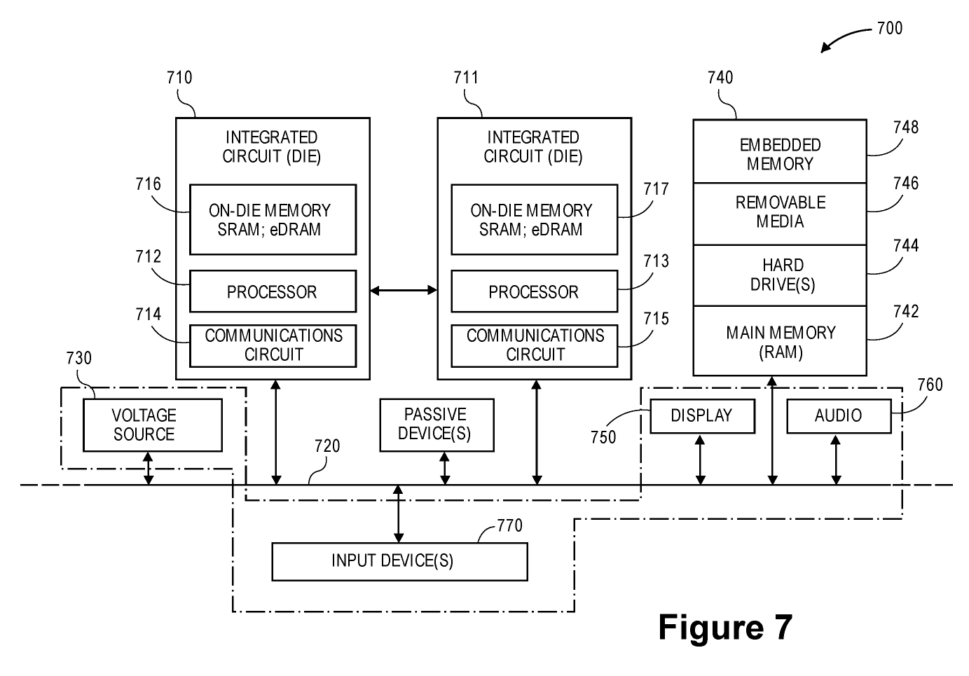

Referring to FIG. 7, a schematic of a computer system is illustrated in accordance with an embodiment. The computer system 700 (also referred to as the electronic system 700) as depicted can embody semiconductor package interposers having high-density and high-aspect ratio encapsulated interconnects, according to any of the several disclosed embodiments and their equivalents as set forth in this disclosure. The computer system 700 may be a mobile device such as a netbook computer. The computer system 700 may be a mobile device such as a wireless smart phone. The computer system 700 may be a desktop computer. The computer system 700 may be a hand-held reader. The computer system 700 may be a server system. The computer system 700 may be a supercomputer or high-performance computing system.

In an embodiment, the electronic system 700 is a computer system that includes a system bus 720 to electrically couple the various components of the electronic system 700. The system bus 720 is a single bus or any combination of busses according to various embodiments. The electronic system 700 includes a voltage source 730 that provides power to the integrated circuit 710. In some embodiments, the voltage source 730 supplies current to the integrated circuit 710 through the system bus 720.

The integrated circuit 710 is electrically coupled to the system bus 720 and includes any circuit, or combination of circuits according to an embodiment. In an embodiment, the integrated circuit 710 includes a processor 712 that can be of any type. As used herein, the processor 712 may mean any type of circuit such as, but not limited to, a microprocessor, a microcontroller, a graphics processor, a digital signal processor, or another processor. In an embodiment, the processor 712 includes, or is coupled with, semiconductor package interposers having high-density and high-aspect ratio encapsulated interconnects, as disclosed herein. In an embodiment, SRAM embodiments are found in memory caches of the processor. Other types of circuits that can be included in the integrated circuit 710 are a custom circuit or an application-specific integrated circuit (ASIC), such as a communications circuit 714 for use in wireless devices such as cellular telephones, smart phones, pagers, portable computers, two-way radios, and similar electronic systems, or a communications circuit for servers. In an embodiment, the integrated circuit 710 includes on-die memory 716 such as static random-access memory (SRAM). In an embodiment, the integrated circuit 710 includes embedded on-die memory 716 such as embedded dynamic random-access memory (eDRAM).

In an embodiment, the integrated circuit 710 is complemented with a subsequent integrated circuit 711. Useful embodiments include a dual processor 713 and a dual communications circuit 715 and dual on-die memory 717 such as SRAM. In an embodiment, the dual integrated circuit 711 includes embedded on-die memory 717 such as eDRAM.

In an embodiment, the electronic system 700 also includes an external memory 740 that in turn may include one or more memory elements suitable to the particular application, such as a main memory 742 in the form of RAM, one or more hard drives 744, and/or one or more drives that handle removable media 746, such as diskettes, compact disks (CDs), digital variable disks (DVDs), flash memory drives, and other removable media known in the art. The external memory 740 may also be embedded memory 748 such as the first die in a die stack, according to an embodiment.

In an embodiment, the electronic system 700 also includes a display device 750, and an audio output 760. In an embodiment, the electronic system 700 includes an input device such as a controller 770 that may be a keyboard, mouse, trackball, game controller, microphone, voice-recognition device, or any other input device that inputs information into the electronic system 700. In an embodiment, an input device 770 is a camera. In an embodiment, an input device 770 is a digital sound recorder. In an embodiment, an input device 770 is a camera and a digital sound recorder.

As shown herein, the integrated circuit 710 can be implemented in a number of different embodiments, including a semiconductor package assembly having a semiconductor package interposer having high-density and high-aspect ratio encapsulated interconnects, according to any of the several disclosed embodiments and their equivalents, an electronic system, a computer system, one or more methods of fabricating an integrated circuit, and one or more methods of fabricating an electronic assembly that includes a semiconductor package interposer having high-density and high-aspect ratio encapsulated interconnects, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed semiconductor package assemblies having semiconductor package interposers having high-density and high-aspect ratio encapsulated interconnect embodiments and their equivalents. A foundation substrate may be included, as represented by the dashed line of FIG. 7. Passive devices may also be included, as is also depicted in FIG. 7.

In an embodiment, a semiconductor package interposer includes a polymer substrate having a first end face separated from a second end face in a longitudinal direction. The semiconductor package interposer includes several conductive interconnects encapsulated by the polymer substrate. The conductive interconnects extend in the longitudinal direction from respective first ends exposed at the first end face of the polymer substrate to respective second ends exposed at the second end face of the polymer substrate.

In one embodiment, the polymer substrate includes a polymer sheet encapsulating the conductive interconnects. The polymer sheet includes a sidewall face extending from the first end face to the second end face.

In one embodiment, the conductive interconnects extend parallel to each other in the longitudinal direction. Each conductive interconnect includes a height in the longitudinal direction and a cross-section orthogonal to the longitudinal direction. The height is at least 1.5 times greater than a dimension across the cross-section.

In one embodiment, the conductive interconnects have a pitch in a transverse direction orthogonal to the longitudinal direction. The pitch is in a range of 200 to 250 microns.

In one embodiment, the cross-section is rectangular. The dimension is a width dimension in the transverse direction or a depth dimension in a depth direction orthogonal to the longitudinal direction and the transverse direction. The dimension is in a range of 50 to 200 microns.

In an embodiment, a semiconductor package assembly includes a first semiconductor package having several first contact pads. The semiconductor package assembly includes a second semiconductor package having several second contact pads. The semiconductor package assembly includes an interposer having several conductive interconnects encapsulated by a polymer substrate. The conductive interconnects extend in a longitudinal direction from respective first ends exposed at a first end face of the polymer substrate to respective second ends exposed at a second end face of the polymer substrate. The first ends are electrically connected to respective first contact pads of the first semiconductor package and the second ends are electrically connected to respective second contact pads of the second semiconductor package.

In one embodiment, the first semiconductor package includes a logic die, the second semiconductor package includes a memory die, and the interposer supports the memory die above the logic die.

In one embodiment, the first semiconductor package and the second semiconductor package include respective package sides. The polymer substrate of the interposer includes a sidewall face extending parallel to the package sides.

In one embodiment, the polymer substrate includes a polymer sheet encapsulating the conductive interconnects. The polymer sheet includes the sidewall face extending from the first end face to the second end face.

In one embodiment, the conductive interconnects extend parallel to each other in the longitudinal direction. Each conductive interconnect includes a height in the longitudinal direction and a cross-section orthogonal to the longitudinal direction. The height is at least 1.5 times greater than a dimension across the cross-section.

In one embodiment, the conductive interconnects have a pitch in a transverse direction orthogonal to the longitudinal direction. The pitch is in a range of 200 to 250 microns.

In an embodiment, a method of manufacturing a semiconductor package interposer includes fabricating a comblike frame having a spine and several conductive interconnects. The conductive interconnects extend in a longitudinal direction from respective first ends at the spine to respective second ends. The method includes embedding the conductive interconnects in a polymer substrate. The conductive interconnects extend through the polymer substrate from the first ends to the second ends. The method includes removing the spine from the conductive interconnects to expose the first ends of the conductive interconnects at a first end face of the polymer substrate. The method includes removing a portion of the polymer substrate to expose the second ends of the conductive interconnects at a second end face of the polymer substrate.

In one embodiment, fabricating the comblike frame includes stamping the comblike frame from a sheet of conductive material.

In one embodiment, embedding the conductive interconnects includes encapsulating one or more of the spine or the second ends of the conductive interconnects in the polymer substrate.

In one embodiment, embedding the conductive interconnects includes overmolding the polymer substrate around the conductive interconnects.

In one embodiment, removing the spine includes cutting through the polymer substrate and the conductive interconnects in a transverse direction orthogonal to the longitudinal direction.

In one embodiment, the method includes attaching the first ends of the conductive interconnects to respective first contact pads of a first semiconductor package. The method includes attaching the second ends of the conductive interconnects to respective second contact pads of a second semiconductor package.

In one embodiment, one or more of attaching the first ends to the first contact pads or attaching the second ends to the second contact pads includes soldering the respective ends to the respective pads.

In one embodiment, the conductive interconnects extend parallel to each other in the longitudinal direction. Each conductive interconnect includes a height in the longitudinal direction and a cross-section orthogonal to the longitudinal direction. The height is at least 1.5 times greater than a dimension across the cross-section.

In one embodiment, the conductive interconnects have a pitch in a transverse direction orthogonal to the longitudinal direction. The pitch is in a range of 200 to 250 microns.

1. A semiconductor package interposer, comprising:
a polymer substrate having a column profile extending in a longitudinal direction, wherein the column profile includes a first end face separated from a second end face by a height in the[[a]] longitudinal direction, wherein the column profile has a first sidewall separated from a second sidewall by a depth in a lateral direction orthogonal to the longitudinal direction, wherein the height is greater than the depth, and wherein the first sidewall and second sidewall are exposed; and
a plurality of conductive interconnects encapsulated by the polymer substrate, wherein the conductive interconnects extend in the longitudinal direction parallel to the exposed sidewalls from respective first ends exposed at the first end face of the polymer substrate to respective second ends exposed at the second end face of the polymer substrate.

2. The semiconductor package interposer of claim 1, wherein the polymer substrate includes a polymer sheet encapsulating the conductive interconnects, and wherein the polymer sheet includes the exposed sidewalls of the column profile.

3. The semiconductor package interposer of claim 2, wherein the conductive interconnects extend parallel to each other in the longitudinal direction, wherein each conductive interconnect includes the height in the longitudinal direction and a cross-section orthogonal to the longitudinal direction, and wherein the height is at least 1.5 times greater than the depth.

4. The semiconductor package interposer of claim 3, wherein the conductive interconnects have a pitch in a transverse direction orthogonal to the longitudinal direction and the lateral direction, and wherein the pitch is in a range of 200 to 250 microns.

5. The semiconductor package interposer of claim 4, wherein the cross-section is rectangular, wherein the dimension is a width dimension in the transverse direction or a depth dimension in the lateral direction, and wherein the dimension is in a range of 50 to 200 microns.

6. A semiconductor package assembly, comprising:
a first semiconductor package having a plurality of first contact pads;
a second semiconductor package having a plurality of second contact pads; and
an interposer having a plurality of conductive interconnects encapsulated by a polymer substrate, wherein the polymer substrate has a column profile extending in a longitudinal direction, wherein the column profile includes a first end face separated from a second end face by a height in the longitudinal direction, wherein the column profile has a first sidewall separated from a second sidewall by a depth in a lateral direction orthogonal to the longitudinal direction, wherein the height is greater than the depth, wherein the first sidewall and second sidewall are exposed, wherein the conductive interconnects extend in the longitudinal direction parallel to the exposed sidewalls from respective first ends exposed at a first end face of the polymer substrate to respective second ends exposed at a second end face of the polymer substrate, and wherein the first ends are electrically connected to respective first contact pads of the first semiconductor package and the second ends are electrically connected to respective second contact pads of the second semiconductor package.

7. The semiconductor package assembly of claim 6, wherein the first semiconductor package includes a logic die, wherein the second semiconductor package includes a memory die, and wherein the interposer supports the memory die above the logic die.

8. The semiconductor package assembly of claim 7, wherein the first semiconductor package and the second semiconductor package include respective package sides, and wherein the exposed sidewalls of the column profile extend parallel to the package sides.

9. The semiconductor package assembly of claim 8, wherein the polymer substrate includes a polymer sheet encapsulating the conductive interconnects, and wherein the polymer sheet includes the exposed sidewalls of the column profile.

10. The semiconductor package assembly of claim 6, wherein the conductive interconnects extend parallel to each other in the longitudinal direction, wherein each conductive interconnect includes the height in the longitudinal direction and a cross-section orthogonal to the longitudinal direction, and wherein the height is at least 1.5 times greater than the depth.

11. The semiconductor package assembly of claim 10, wherein the conductive interconnects have a pitch in a transverse direction orthogonal to the longitudinal direction, and wherein the pitch is in a range of 200 to 250 microns.

12. A method, comprising:
fabricating a comblike frame having a spine and a plurality of conductive interconnects, wherein the conductive interconnects extend in a longitudinal direction from respective first ends at the spine to respective second ends;
embedding the conductive interconnects in a polymer substrate, wherein the conductive interconnects extend through the polymer substrate from the first ends to the second ends wherein the polymer substrate has a column profile extending in the longitudinal direction, wherein the column profile includes a first end face separated from a second end face by a height in the longitudinal direction, wherein the column profile has a first sidewall separated from a second sidewall by a depth in a lateral direction orthogonal to the longitudinal direction, wherein the height is greater than the depth, and wherein the first sidewall and second sidewall are exposed and extend parallel to the conductive interconnects;
removing the spine from the conductive interconnects to expose the first ends of the conductive interconnects at the first end face of the polymer substrate; and
removing a portion of the polymer substrate to expose the second ends of the conductive interconnects at the second end face of the polymer substrate.

13. The method of claim 12, wherein fabricating the comblike frame includes stamping the comblike frame from a sheet of conductive material.

14. The method of claim 12, wherein embedding the conductive interconnects includes encapsulating one or more of the spine or the second ends of the conductive interconnects in the polymer substrate.

15. The method of claim 14, wherein embedding the conductive interconnects includes overmolding the polymer substrate around the conductive interconnects.

16. The method of claim 12, wherein removing the spine includes cutting through the polymer substrate and the conductive interconnects in a transverse direction orthogonal to the longitudinal direction.

17. The method of claim 12 further comprising:
attaching the first ends of the conductive interconnects to respective first contact pads of a first semiconductor package; and
attaching the second ends of the conductive interconnects to respective second contact pads of a second semiconductor package.

18. The method of claim 17, wherein one or more of attaching the first ends to the first contact pads or attaching the second ends to the second contact pads includes soldering the respective ends to the respective pads.

19. The method of claim 12, wherein the conductive interconnects extend parallel to each other in the longitudinal direction, wherein each conductive interconnect includes the height in the longitudinal direction and a cross-section orthogonal to the longitudinal direction, and wherein the height is at least 1.5 times greater than a dimension across the cross-section.

20. The method of claim 19, wherein the conductive interconnects have a pitch in a transverse direction orthogonal to the longitudinal direction and the lateral direction, and wherein the pitch is in a range of 200 to 250 microns.
